(19) United States
(12) Patent Application Publication
(10) Pub. No.: US 2024/0231828 A9
(43) Pub. Date: Jul. 11, 2024

(54) INSTRUCTION COMPRESSION METHOD, INSTRUCTION DECOMPRESSION METHOD AND PROCESS COMPRESSION METHOD

(71) Applicant: SigmaStar Technology Ltd., Xiamen (CN)

(72) Inventor: Ya Ming Deng, Shanghai (CN)

(21) Appl. No.: 18/376,454

(22) Filed: Oct. 4, 2023

(30) Foreign Application Priority Data
Oct. 21, 2022 (CN) 202211295072.4

(51) Int. Cl. G06F 9/30

(52) U.S. Cl. CPC G06F 9/30178; G06F 9/30112

(57) ABSTRACT

A process compression method for compressing a process that includes a jump instruction includes the following steps: dividing the process into multiple blocks according to a position of the jump instruction in the process and a destination of the jump instruction; storing a jump relationship between these blocks; performing instruction compression on these blocks; updating a jump address of the jump instruction according to the jump relationship; determining multiple groups according to the sizes of the blocks and the jump relationship; and determining whether the jump instruction is a jump instruction of a first type or a jump instruction of a second type according to the relationship between the jump instruction and the groups.

This application claims the benefit of China application Serial No. 202211295072.4, filed on Oct. 21, 2022, the subject matter of which is incorporated herein by reference.

### BACKGROUND OF THE INVENTION

### 1. Field of the Invention

The present invention generally relates to instruction compression and instruction decompression, and, more particularly, to instruction compression and instruction decompression related to jump instructions (also referred to as branch instructions).

### 2. Description of Related Art

Generally speaking, a process (e.g., an image processing process, a booting process, etc.) usually includes at least one jump instruction. However, the platforms on the market cannot enable variable-length instruction compression when processing jump logic, which leads to the requirement for a larger instruction register, an increase in the number of long jump instructions, and a decrease in the process execution efficiency. Therefore, there is a need for an instruction compression method, an instruction decompression method, and a process compression method to reduce the space required by the instruction register and the number of long jump instructions.

### SUMMARY OF THE INVENTION

In view of the issues of the prior art, an object of the present invention is to provide an instruction compression method, an instruction decompression method, and a process compression method, so as to make an improvement to the prior art.

According to one aspect of the present invention, an instruction decompression method is provided. The instruction decompression method is applied to a hardware circuit that decompresses an instruction and executes the instruction. The instruction includes a header, and the header includes a reference value. The instruction decompression method includes the following steps: reading a first parameter of the instruction to obtain a total number of mismatched parameters when the reference value of the instruction is a preset value; and using a plurality of second parameters of the instruction to set a plurality of corresponding parameters of the hardware circuit, the number of second parameters is equal to the total number of mismatched parameters.

According to another aspect of the present invention, an instruction compression method is provided. The instruction compression method is for compressing an instruction to generate a compressed instruction. The instruction includes a header and a plurality of parameters, and the header includes a reference value. The instruction compression method includes the following steps: comparing the instruction with a previous instruction to find a plurality of mismatched parameters between the instruction and the previous instruction; setting the reference value of the compressed instruction to a preset value; setting a target parameter of the compressed instruction to the number of mismatched parameters; and setting other parameters of the compressed instruction to the mismatched parameters.

According to still another aspect of the present invention, a process compression method is provided. The process compression method is for compressing a process that includes a jump instruction. The process compression method includes the following steps: dividing the process into a plurality of blocks according to a position of the jump instruction in the process and a destination of the jump instruction; storing a jump relationship between the blocks; performing instruction compression on the blocks; recalculating a jump address of the jump instruction according to the jump relationship; determining a plurality of groups according to sizes of the blocks and the jump relationship; and determining whether the jump instruction is a jump instruction of a first type or a jump instruction of a second type according to a relationship between the jump instruction and the groups.

The technical means embodied in the embodiments of the present invention can solve at least one of the problems of the prior art. Therefore, compared with the prior art, the present invention can reduce the space required by the instruction register and/or the number of long jump instructions.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 is a functional block diagram of an Intelligent Processing Unit (IPU) according to an embodiment of the present invention.

FIG. 2 is a flowchart of a process compression method according to an embodiment of the present invention.

FIG. 3 shows a process including multiple instructions, and an inter-block jump relationship of the process.

FIG. 4 is a schematic diagram of an inter-block jump relationship.

FIG. 5 is the detail of step S210 of FIG. 2 according to an embodiment.

FIG. 6 is the flowchart of an instruction compression method according to an embodiment of the present invention.

FIG. 7 is a schematic diagram of instruction structures before and after compression.

FIG. 8 and FIG. 9 are details of step S250 of FIG. 2 according to an embodiment.

FIG. 10A and FIG. 10B are schematic diagrams of grouping multiple blocks of a process into multiple groups according to an embodiment of the present invention.

FIG. 11 is the detail of step S260 of FIG. 2 according to an embodiment.

FIG. 12 is a schematic diagram of grouping according to another embodiment of the present invention.

FIG. 13 is a flowchart of an instruction decompression method according to an embodiment of the present invention.

FIG. 14 is a schematic diagram of the execution of uncompressed instructions by a hardware circuit of the present invention.

FIG. 15 is a schematic diagram of the execution of compressed instructions by a hardware circuit of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes an instruction compression method, an instruction decompression method, and a process compression method. On account of that some or all elements of the Intelligent Processing Unit (IPU) could be known, the detail of such elements is omitted provided that such detail has little to do with the features of this disclosure, and that this omission nowhere dissatisfies the specification and enablement requirements. Some or all of the processes of the instruction compression method, the instruction decompression method, and the process compression method may be implemented by software and/or firmware. A person having ordinary skill in the art can choose components or steps equivalent to those described in this specification to carry out the present invention, which means that the scope of this invention is not limited to the embodiments in the specification.

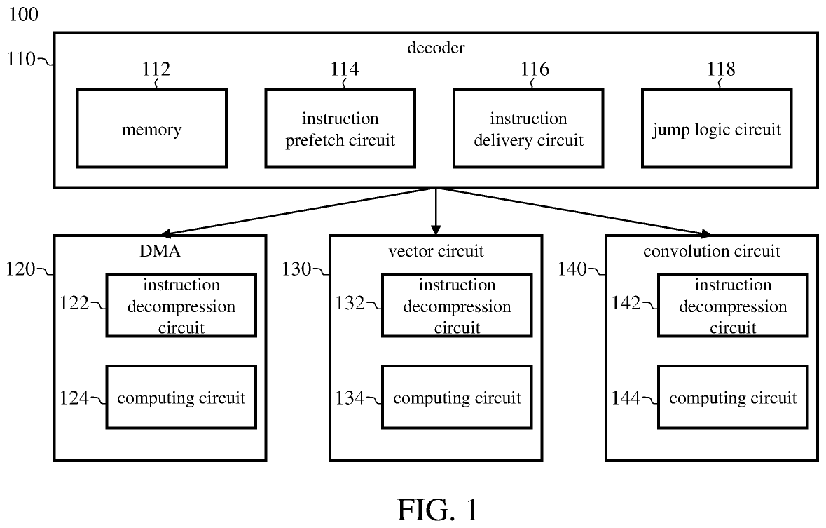

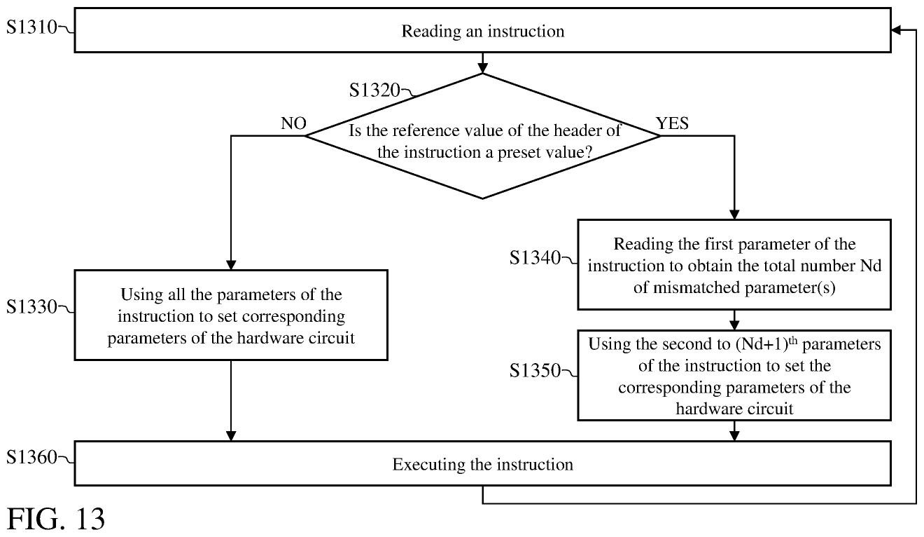

FIG. 1 is a functional block diagram of an Intelligent Processing Unit (IPU) according to an embodiment of the present invention. The IPU 100 includes a decoder 110, a direct memory access (DMA) 120, a vector circuit 130, and a convolution circuit 140. The DMA 120, the vector circuit 130, and the convolution circuit 140 respectively include the instruction decompression circuits 122, 132, 142 and the computing circuits 124, 134, 144. The instruction decompression circuits 122, 132, and 142 are used to decompress instructions (details of decompressing instructions will be discussed later in connection with FIG. 13), and the computing circuits 124, 134, and 144 carry out the main functions of the DMA 120, the vector circuit 130, and the convolution circuit 140, respectively. The main functions of the DMA 120, the vector circuit 130, and the convolution circuit 140 are known to people having ordinary skill in the art and shall be omitted herein.

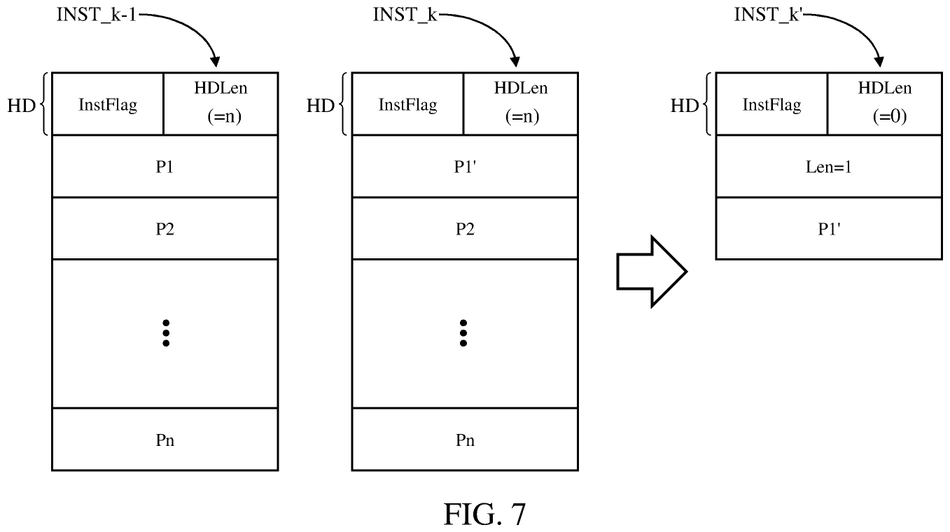

The decoder 110 includes a memory 112 (e.g., a Static Random Access Memory (SRAM)), an instruction prefetch circuit 114, an instruction delivery circuit 116, and a jump logic circuit 118. The memory 112 can store instructions to be executed by the IPU 100. The instruction prefetch circuit 114 is used to fetch the instruction from the memory 112, and then the instruction delivery circuit 116 delivers the instruction to the corresponding hardware circuit (i.e., the DMA 120, the vector circuit 130, or the convolution circuit 140) according to the flag InstFlag of the instruction (reference can be made to FIG. 7). The jump logic circuit 118 is used to determine whether the instruction is a jump instruction and/or the type of the jump instruction (long jump instruction or short jump instruction). When processing a jump instruction, the jump logic circuit 118 determines the destination of the jump instruction, and then the instruction prefetch circuit 114 fetches the next instruction according to the destination.

In some embodiments, if the difference between the destination of a jump instruction (i.e., the address of the target instruction in the memory 112) and the address of the jump instruction itself in the memory 112 is less than a threshold (e.g., the size of the instruction buffer of the memory 112), then the jump instruction is a short jump instruction; otherwise, the jump instruction is a long jump instruction. That is to say, the jump range of a short jump instruction is smaller than the jump range of a long jump instruction. When processing long jump instructions, the decoder 110 needs the DMA 120 to get more instructions from the external memory of the IPU 100 (e.g., a Dynamic Random Access Memory (DRAM), not shown); however, there is no such a need for short jump instructions. Therefore, long jump instructions consume more time and system resources than short jump instructions.

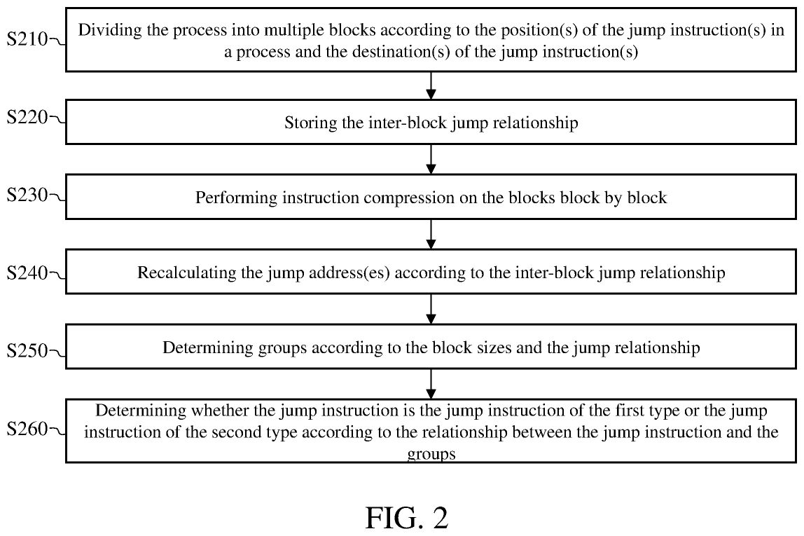

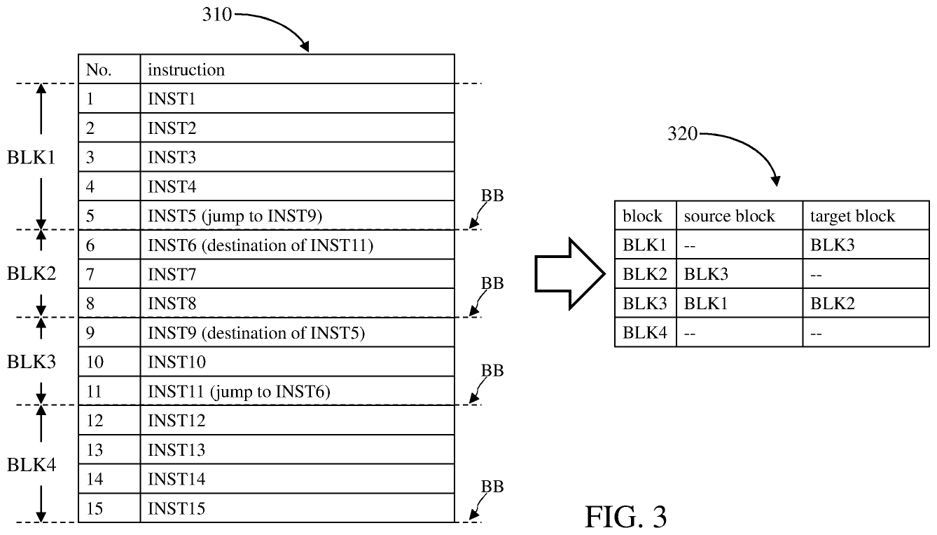

FIG. 2 is a flowchart of a process compression method according to an embodiment of the present invention. In some embodiments, the steps of FIG. 2 are performed by a development tool (e.g., a general-purpose computer) during the development of the IPU 100. The process compression method in FIG. 2 can be used to compress a process (e.g., an image processing process, a booting process, etc.), and the process contains multiple instructions (for example, the process 310 in FIG. 3 includes 15 instructions (INST1 to INST15), these instructions are variable-length instructions, and at least one of them is a jump instruction. FIG. 3 will be discussed in detail below). FIG. 2 includes the following steps.

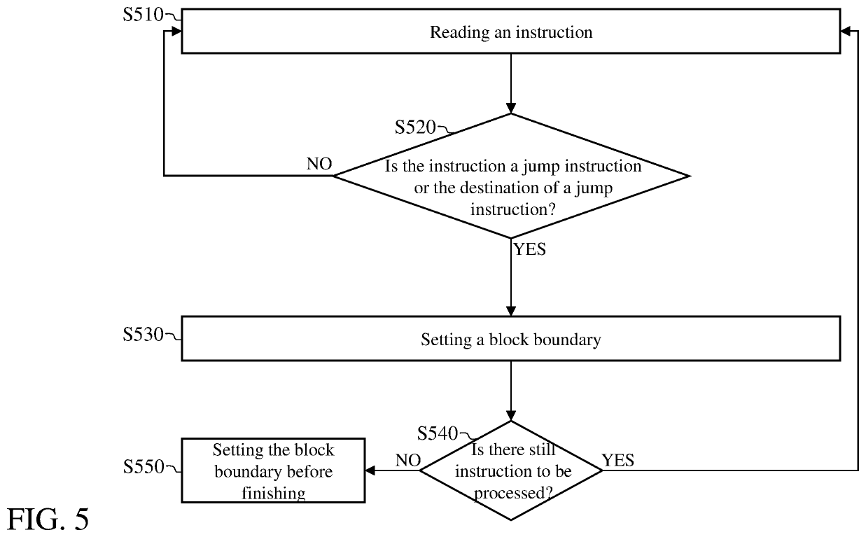

Step S210: Dividing the process into multiple blocks according to the position(s) of the jump instruction(s) in a process (e.g., the address(es) of the jump instruction(s) in the memory 112) and the destination(s) of the jump instruction(s) (e.g., the address(es) of the destination(s) in the memory 112). More specifically, step S210 scans the instructions in a process and sets at least one block boundary BB to divide the process into multiple blocks. The details of step S210 will be discussed in detail below in connection with FIG. 5. In the example of FIG. 3, the process 310 is divided into four blocks (BLK1 to BLK4, respectively including instructions INST1 to INST5, instructions INST6 to INST8, instructions INST9 to INST11, and instructions INST12 to INST15, wherein the instruction INST5 and the instruction INST11 are jump instructions, and their destinations are the instruction INST9 and the instruction INST6, respectively).

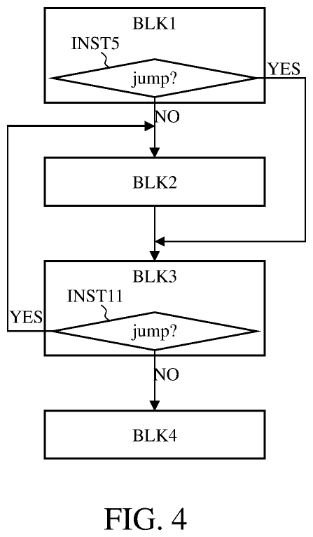

Step S220: Storing the inter-block jump relationship (i.e., a jump relationship between blocks). Reference is made to FIG. 3, when the step S210 finishes, an inter-block jump relationship 320 is generated as follows: the target block of the block BLK1 is the block BLK3 (because the block BLK3 contains the destination of the instruction INST5 (i.e., the instruction INST9)); the source block of the block BLK2 is the block BLK3 (because the block BLK2 contains the destination of the instruction INST11 (i.e., the instruction INST6)); and the source block and the target block of the block BLK3 are the block BLK1 and the block BLK2, respectively. Reference is made to FIG. 4 which shows a schematic diagram of the inter-block jump relationship corresponding to the inter-block jump relationship 320 in FIG. 3. In other words, the inter-block jump relationship can also be represented or stored in graphics.

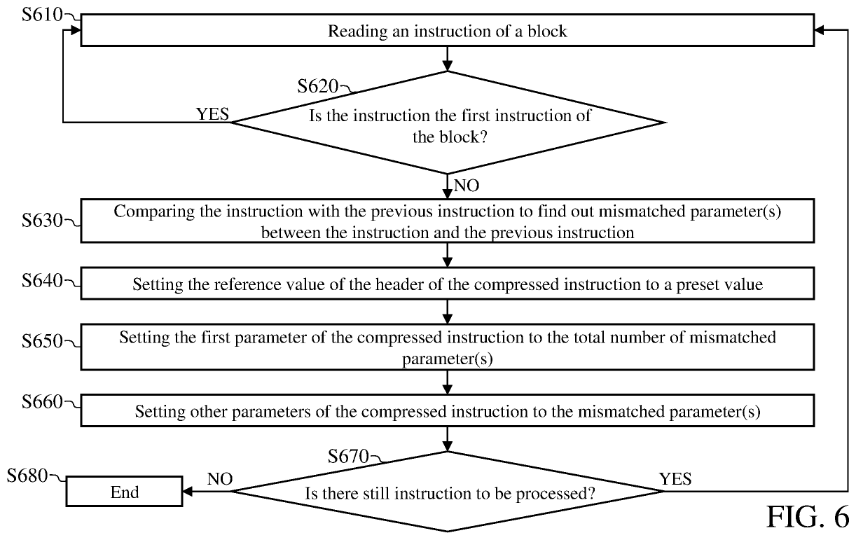

Step S230: Performing instruction compression on the blocks block by block to obtain multiple compressed blocks. This step will be discussed in detail below in connection with FIG. 6.

Step S240: Recalculating the jump address(es) (i.e., the destination address of the jump instruction) according to the inter-block jump relationship. Because the blocks have been compressed in step S230, the address of the destination of the compressed jump instruction is no longer the original address before compression, the jump address must be recalculated or updated. For example (referring to FIG. 3), since almost every block becomes smaller after compression, the positions of the instructions INST9 and INST6 change; thus, the addresses of the destinations of the instructions INST5 and INST11 must be updated or adjusted accordingly.

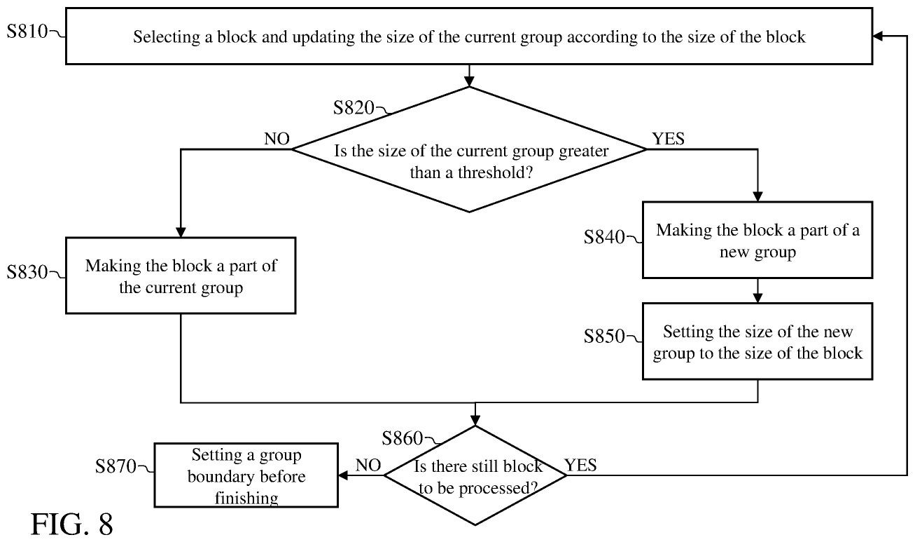

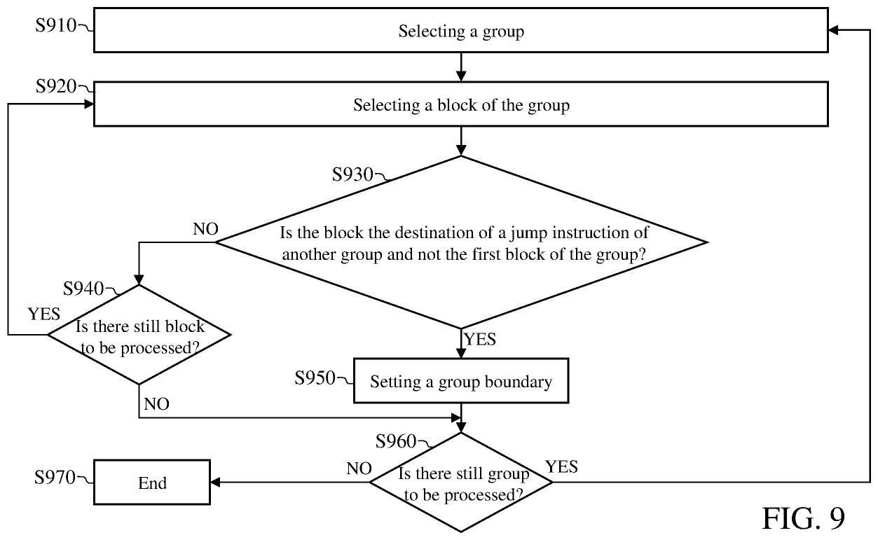

Step S250: Determining groups according to the block sizes and the jump relationship. The purpose of this step is to divide the blocks into groups. The details of step S250 will be discussed below in connection with FIGS. 8-9.

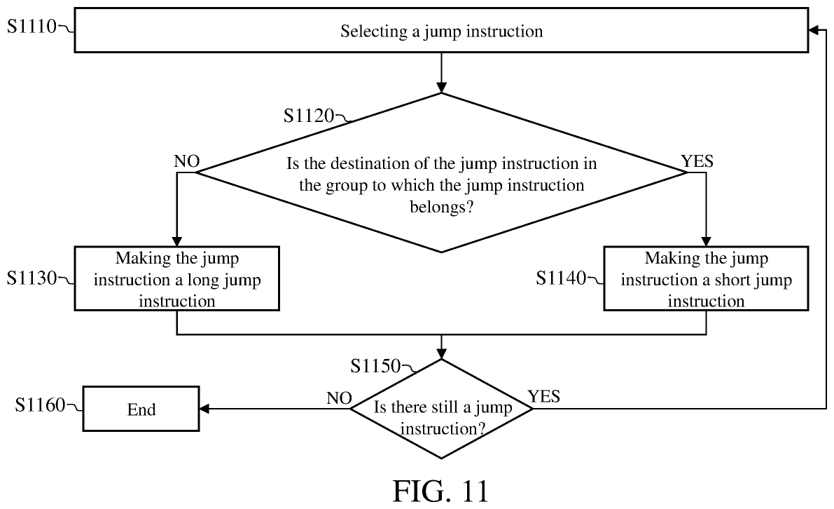

Step S260: Determining whether the jump instruction is the jump instruction of the first type (e.g., the short jump instruction) or the jump instruction of the second type (e.g., the long jump instruction) according to the relationship between the jump instruction and the groups. By grouping the blocks into multiple groups, the present invention can more accurately separate short jump instructions from long jump instructions to avoid errors during the execution of the process. Step S260 will be discussed below in connection with FIG. 11.

FIG. 5 shows the details of step S210, including step S510 to step S550. Reference is made to both FIG. 3 and FIG. 4 for the following discussion.

Step S510: Reading an instruction.

Step S520: Determining whether the instruction is a jump instruction or the destination of a jump instruction. If NO, then the flow proceeds to step S510 to read the next instruction; if YES, the flow proceeds to step S530.

Step S530: Setting a block boundary BB to determine a block. More specifically, if the instruction is a jump instruction, step S530 sets a block boundary BB after the instruction (e.g., between the instruction INST5 and the instruction INST6 and between the instruction INST11 and the instruction INST12 in FIG. 3); if the instruction is the destination of a jump instruction, step S530 sets a block boundary BB before the instruction (e.g., between the instruction INST5 and the instruction INST6 and between the instruction INST8 and the instruction INST9 in FIG. 3).

Step S540: Determining whether there is still instruction to be processed in the process. If YES, then the flow proceeds to step S510 to read the next instruction; if NO, the flow proceeds to step S550.

Step S550: Setting the block boundary BB before finishing.

Taking FIG. 3 as an example, the method in FIG. 5 divides the process 310 (i.e., sets the block boundary BB) at the instruction INST5 to generate the block BLK1. Similarly, since the instruction INST9 and the instruction INST11 are a destination and a jump instruction, respectively, the block boundaries BB are set before the instruction INST9 and after the instruction INST11, thus generating the block BLK2 and the block BLK3, respectively. At the end of the process 310, a block boundary BB is also set to generate the block BLK4.

FIG. 6 is a flowchart of an instruction compression method according to an embodiment of the present invention. FIG. 7 is a schematic diagram of an instruction structure before compression and an instruction structure after compression. As shown in FIG. 7, the instruction INST_k−1 and the instruction INST_k are uncompressed instructions (they are successive instructions, and the instruction INST_k−1 is before the instruction INST_k). The instruction INST_k−1, the instruction INST_k, and the compressed instruction INST_k′ all include a header HD and at least one parameter (e.g., the instruction INST_k−1 and the instruction INST_k each include n parameters P1 (or P1′) to Pn, and the compressed instruction INST_k′ includes one parameter P1′). In some embodiments, the header HD and the parameters are each one word in size. The header HD includes a flag InstFlag and a reference value HDLen. The flag InstFlag indicates the hardware circuit to which the instruction belongs. For uncompressed instructions, the reference value HDLen stores the number of parameters (e.g., the reference value HDLen of the instruction INST_k−1 and the instruction INST_k is n); for the compressed instruction INST_k′, the reference value HDLen is a preset value (e.g., 0). The compression method in FIG. 6 is on a block-by-block basis and includes the following steps.

Step S610: Reading an instruction of a block.

Step S620: Determining whether the instruction is the first instruction of the block. If YES, then the flow proceeds to step S610 to read the next instruction of the block; if NO, the flow proceeds to step S630. Instruction compression is not performed on the first instruction of a block because there is no previous instruction to be used as a reference.

Step S630: Comparing the instruction with the previous instruction to find out mismatched parameter(s) between the instruction and the previous instruction. Taking FIG. 7 as an example, since the parameters P2 to Pn of the instruction INST_k−1 are respectively identical to the parameters P2 to Pn of the instruction INST_k, and only the parameter P1 is different from the parameter P1′, the mismatched parameter found in step S630 is the parameter P1′.

Step S640: Setting the reference value HDLen of the header HD of the compressed instruction to the preset value to mark the compressed instruction.

Step S650: Setting the first parameter of the compressed instruction to the total number Nd of mismatched parameter(s). Taking FIG. 7 as an example, since the total number Nd of mismatched parameter(s) between the instruction INST_k−1 and the instruction INST_k is 1, this step sets the first parameter of the compressed instruction INST_k′ to 1 (i.e., “Len=1”).

Step S660: Setting other parameters of the compressed instruction to the mismatched parameter(s). This step sets the second to x^{th} (x=1+Nd) parameter(s) of the compressed instruction INST_k′ to the mismatched parameter(s) obtained in step S630. Taking FIG. 7 as an example, because the only mismatched parameter between the instruction INST_k−1 and the instruction INST_k is the parameter P1′ (i.e., the total number Nd of mismatched parameter(s) is 1), this step sets the second parameter of the compressed instruction INST_k′ to the parameter P1′. After step S660 is finished, the compressed instruction INST_k′ can be obtained.

Step S670: Determining whether there is still instruction to be processed in the block. If YES, the flow proceeds to step S610 to read the next instruction of the block; if NO, the method of FIG. 6 ends (step S680).

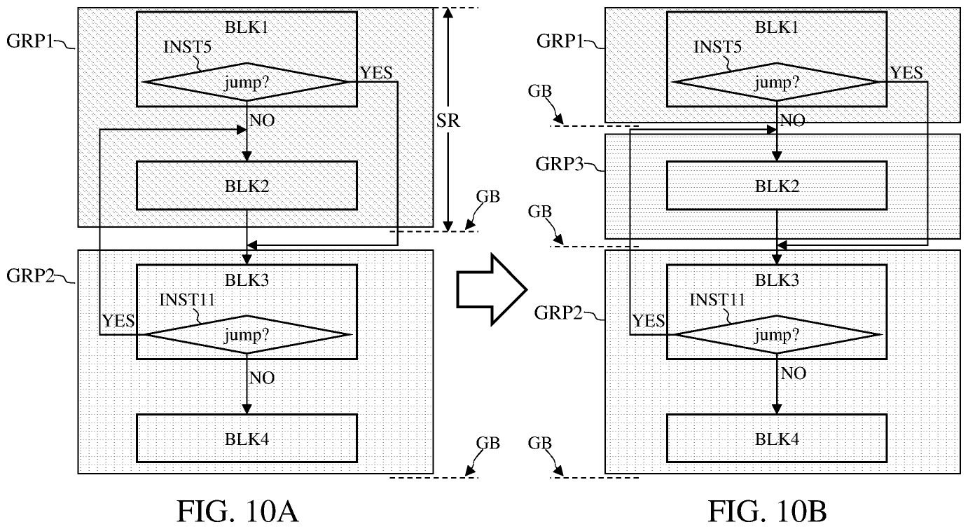

FIGS. 8 and 9 are details of step S250 in FIG. 2 according to an embodiment. Step S250 includes two main steps: first, determining groups according to the block size (FIG. 8), and then adjusting the groups according to the jump relationship (FIG. 9). For the following discussion, reference is made to FIG. 10A and FIG. 10B together. FIG. 10A and FIG. 10B are, according to an embodiment of the present invention, schematic diagrams of grouping multiple blocks of the process into multiple groups, which corresponds to the process 310 in FIG. 3. FIG. 8 includes the following steps.

Step S810: Selecting a block and updating the size of the current group according to the size of the block. The size of a group is the sum of the sizes of all the blocks contained in that group. This step updates the size of the current group to the sum of the size of the current group and the size of the block. Taking FIG. 10A as an example, if the current group includes only the block BLK1, then the selected block is the block BLK2, and the size of the updated current group is the sum of the size of the block BLK1 and the size of the block BLK2.

Step S820: Determining whether the size of the current group is greater than a threshold. In some embodiments, the threshold may be the size of the instruction buffer of the memory 112. If the result of step S820 is NO, then the flow proceeds to step S830; otherwise, the flow proceeds to step S840 and step S850.

Step S830: Making the block a part of the current group. The result of step S820 being negative means that adding the selected block to the current group does not make the current group too large (greater than the threshold); thus, step S830 makes the block a part of the current group. Continuing the above example, if the sum of the size of the block BLK1 and the size of the block BLK2 does not exceed the threshold SR, this step sets the block BLK2 to be in the same group as the block BLK1.

Step S840: Making the block a part of a new group. The result of step S820 being positive means that adding the selected block to the current group makes the current group too large (greater than the threshold); thus, step S840 determines the current group (i.e., sets the group boundary GB), and then makes the selected block a part of the new group (the new group contains only this block at this time). Taking FIG. 10A as an example, when the selected block is the block BLK3, step S840 first sets the group boundary GB (i.e., to determine the group GRP1) and then establishes the group GRP2 (at this time, the group GRP2 contains only the block BLK3 and has not yet been determined).

Step S850: Setting the size of the new group to the size of the block. Continuing the above example, since the group GRP2 contains only the block BLK3 at this time, the size of the new group is the size of the block BLK3. Note that the new group becomes the current group in the next iteration (i.e., when step S810 is performed again).

Step S860: Determining whether there is still block to be processed. If YES, the flow proceeds to step S810 to select the next block; if NO, the flow proceeds to step S870.

Step S870: Setting a group boundary before finishing. Taking FIG. 10A as an example, when the selected block is the block BLK4, the result of step S860 is NO, and then step S870 sets the group boundary GB after the block BLK4 to determine the group GRP2.

Referring to FIG. 10A, after the method in FIG. 8 finishes, the four blocks in FIG. 4 are divided into two groups. However, because a destination of a jump instruction being in the middle (i.e., between the first block and the last block of a group) of the group GRP1 (e.g., the destination of the instruction INST11 is the block BLK2) is unwanted (because this will cause a jump error during the execution of the process), the group must be further adjusted according to the method in FIG. 9. FIG. 9 includes the following steps.

Step S910: Selecting a group.

Step S920: Selecting a block of the group.

Step S930: Determining whether the following conditions are satisfied: the block is not the first block of the group, and the block is the destination of a jump instruction of another group. Taking FIG. 10A as an example, if step S910 and step S920 respectively select the group GRP1 and the block BLK1, the result of step S830 is NO (because the block BLK1 is the first block of the group GRP1); if step S910 and step S920 respectively select the group GRP1 and the block BLK2, the result of step S830 is YES (because the block BLK2 is not the first block of the group GRP1 and is the destination of the instruction INST11).

Step S940: Determining whether there is still block to be processed in the group. If YES, the flow proceeds to step S920 to select the next block of the group; otherwise, the flow proceeds to step S960.

Step S950: Setting the group boundary GB, that is, dividing the current group into two groups. Taking FIG. 10A and FIG. 10B as an example, step S950 sets the group boundary GB before the block BLK2 (i.e., the destination of the instruction INST11); as a result, the original group GRP1 becomes the group GRP1 and the group GRP3.

Step S960: Determining whether there is still group to be processed. If YES, the flow proceeds to step S910 to select the next group; if NO, the method of FIG. 9 ends (step S970).

FIG. 11 shows the details of step S260 in FIG. 2 according to an embodiment, including the following steps.

Step S1110: Selecting a jump instruction. Taking FIG. 10B as an example, this step selects the instruction INST5 or the instruction INST11.

Step S1120: Determining whether the destination of the jump instruction is in the group to which the jump instruction belongs. Taking FIG. 10B as an example, the result of step S1120 is negative for the instruction INST5 because its destination (the block BLK3) is not in the group to which the instruction INST5 belongs (i.e., the group GRP1). Similarly, for the instruction INST11, the result of step S1120 is also negative.

Step S1130: Making the jump instruction a long jump instruction.

Step S1140: Making the jump instruction a short jump instruction.

Step S1150: Determining whether there is still a jump instruction. If YES, the flow proceeds to step S1110 to select the next jump instruction; if NO, the method of FIG. 11 ends (step S1160).

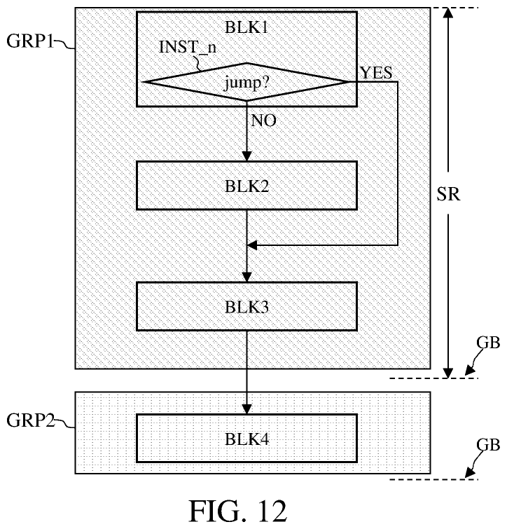

In the example of FIG. 10B, both the instruction INST5 and the instruction INST11 are inter-group jump instructions (long jump instructions). Reference is made to FIG. 12, which is a schematic diagram of grouping according to another embodiment of the present invention. As shown in FIG. 12, the group GRP1 contains the blocks BLK1, BLK2, and BLK3, while the group GRP2 contains only the block BLK4. Since the jump instruction INST_n and its destination (the block BLK3) are both in the group GRP1, the jump instruction INST_n is an intra-group jump instruction. Therefore, the jump instruction INST_n is determined to be a short jump instruction in the method of FIG. 11 (i.e., the result of step S1120 is YES).

FIG. 13 is a flowchart of an instruction decompression method according to an embodiment of the present invention. FIG. 13 is performed by the instruction decompression circuit (i.e., the instruction decompression circuit 122, the instruction decompression circuit 132, or the instruction decompression circuit 142) of the hardware circuit in FIG. 1 (i.e., the DMA 120, the vector circuit 130, or the convolution circuit 140). FIG. 13 includes the following steps.

Step S1310: Reading or receiving an instruction, for example, reading an instruction from the memory, or receiving an instruction delivered by the instruction delivery circuit 116.

Step S1320: Determining whether the reference value HDLen of the header HD of the instruction is a preset value. If NO (meaning that the instruction is not a compressed instruction), the flow proceeds to step S1330; if YES (meaning that the instruction is a compressed instruction), the flow proceeds to step S1340 and step S1350.

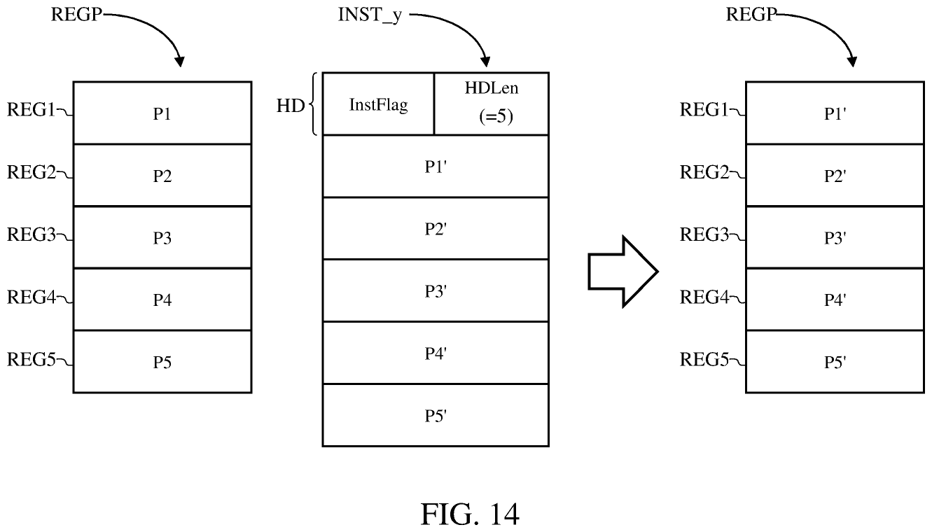

Step S1330: Using all the parameters of the instruction to set corresponding parameters of the hardware circuit (e.g., setting the register values of registers). Reference is made to FIG. 14, which is a schematic diagram of the execution of uncompressed instructions by the hardware circuit of the present invention. If the register group REGP of the hardware circuit stores five parameters: P1, P2, P3, P4, and P5 (which are the register values of the register REG1, the register REG2, the register REG3, the register REG4, and the register REG5, respectively) before the execution of the uncompressed instruction INST_y (which includes five parameters: P1′, P2′, P3′, P4′, and P5′), then after the hardware circuit executes the instruction INST_y, the register group REGP stores the five parameters of the instruction INST_y (as shown in the register group REGP on the right side of FIG. 14). That is to say, the purpose of step S1330 is to set the parameters of the hardware circuit with the parameters of the instruction INST_y. After the parameters of the hardware circuit are set, the hardware circuit (more specifically, the computing circuit of the hardware circuit) can execute the instruction (step S1360).

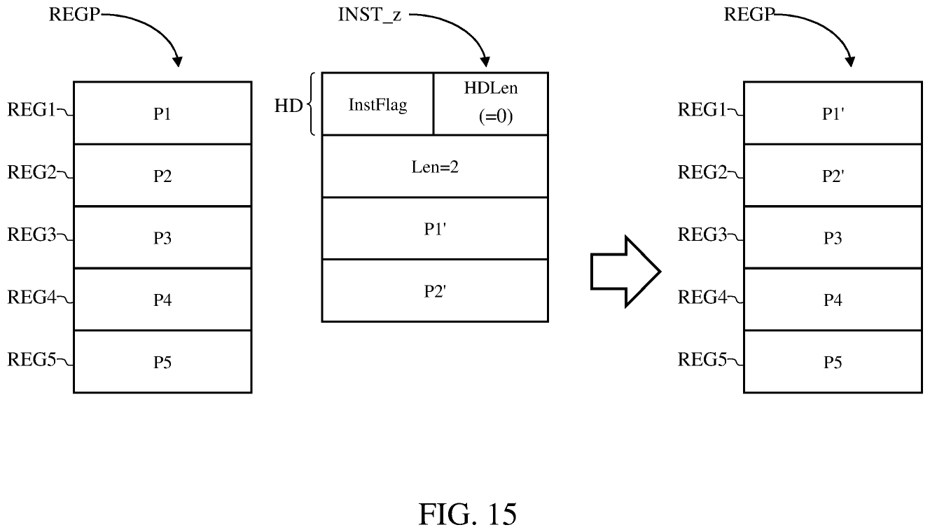

Step S1340: Reading the first parameter of the instruction to obtain the total number Nd of mismatched parameter(s). Reference is made to FIG. 15, which is a schematic diagram of the execution of compressed instructions by the hardware circuit of the present invention. The instruction INST_z in FIG. 15 is a compressed instruction, and total number Nd of mismatched parameter(s) is two (i.e., “Len=2”).

Step S1350: Using the second to (Nd+1)^{th} parameters of the instruction to set the corresponding parameters of the hardware circuit (e.g., setting the register values of the registers). In the example shown in FIG. 15, the instruction decompression circuit obtains the parameter P1′ and parameter P2′ of the compressed instruction INST_z according to the total number Nd of mismatched parameter(s), and then sets the register REG1 and the register REG2 to the parameter P1′ and the parameter P2′, respectively. The purpose of step S1350 is to set the parameters of the hardware circuit with the parameters of the compressed instruction INST_z. After the parameters of the hardware circuit are set, the hardware circuit can execute the instruction (step S1360).

To sum up, by compressing the instructions, the present invention reduces the space that the instruction register requires (i.e., reduces the size of the memory 112) to save cost. In addition, because the instructions are compressed, the present invention can also reduce the number of long jump instructions to improve the execution efficiency of the process.

The variable-length instructions and IPUs are intended to illustrate the invention by way of examples, rather than to limit the scope of the claimed invention. People having ordinary skill in the art may apply the present invention to other types of instructions and control circuits according to the discussions made above.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. An instruction decompression method, wherein the instruction decompression method is applied to a hardware circuit that decompresses an instruction and executes the instruction, the instruction comprises a header, and the header comprises a reference value, the instruction decompression method comprising:
reading a first parameter of the instruction to obtain a total number of mismatched parameters when the reference value of the instruction is a preset value; and
using a plurality of second parameters of the instruction to set a plurality of corresponding parameters of the hardware circuit, the number of second parameters is equal to the total number of mismatched parameters.

2. The method of claim 1 further comprising:
using all parameters of the instruction to set the corresponding parameters of the hardware circuit when the reference value of the instruction is not the preset value.

3. The method of claim 1, wherein the hardware circuit comprises a plurality of registers, and the corresponding parameters are register values of the registers.

4. The method of claim 1, wherein when the total number of mismatched parameters is N, the second parameters are the second parameter to the (N+1)^{th} parameter of the instruction.

5. The method of claim 1, wherein the instruction is a variable-length instruction.

6. An instruction compression method, performed by a computer, for compressing an instruction to generate a compressed instruction, the instruction comprising a header and a plurality of parameters, the header comprising a reference value, the instruction compression method comprising:
comparing the instruction with a previous instruction to find a plurality of mismatched parameters between the instruction and the previous instruction;
setting the reference value of the compressed instruction to a preset value;
setting a target parameter of the compressed instruction to the number of mismatched parameters; and
setting other parameters of the compressed instruction to the mismatched parameters.

7. The method of claim 6, wherein the method is applied to a hardware circuit, the hardware circuit executes a process, the instruction and the previous instruction are successive instructions of the process, and the instruction is after the previous instruction.

8. The method of claim 7, wherein the process comprises a plurality of blocks, each block comprises a plurality of instructions, and the instruction and the previous instruction belong to a same target block of the blocks, and the instruction is not the first instruction of the same target block.

9. The method of claim 6, wherein the target parameter is the first parameter of the compressed instruction.

10. The method of claim 6, wherein the instruction is a variable-length instruction.

11. A process compression method, performed by a computer, for compressing a process that comprises a jump instruction, comprising:
(A) dividing the process into a plurality of blocks according to a position of the jump instruction in the process and a destination of the jump instruction;
(B) storing a jump relationship between the blocks;
(C) performing instruction compression on the blocks;
(D) recalculating a jump address of the jump instruction according to the jump relationship;
(E) determining a plurality of groups according to sizes of the blocks and the jump relationship; and
(F) determining whether the jump instruction is a jump instruction of a first type or a jump instruction of a second type according to a relationship between the jump instruction and the groups.

12. The method of claim 11, wherein the process further comprises a plurality of instructions, and the step (A) comprises:
reading one of the instructions; and
setting a block boundary when the instruction read is the jump instruction or the destination of the jump instruction.

13. The method of claim 12, wherein the instructions are variable-length instructions.

14. The method of claim 11, wherein the step (E) comprises:
selecting a block;
updating a size of a current group according to the size of the block;
making the block a part of a new group when the size of the current group is greater than a threshold; and
making the block a part of the current group when the size of the current group is not greater than the threshold.

15. The method of claim 14, wherein the step (E) further comprises:
setting a size of the new group to the size of the block when the size of the current group is greater than the threshold.

16. The method of claim 14, wherein the jump instruction is a first jump instruction, the destination is a first destination, and the step (E) further comprises:
selecting a first group;
selecting a target block of the first group; and
setting a group boundary when the target block is not the first block of the first group and the target block is a second destination of a second jump instruction of a second group.

17. The method of claim 11, wherein the step (F) comprises:
selecting the jump instruction;
making the jump instruction a short jump instruction when the destination of the jump instruction is in a target group to which the jump instruction belongs.

18. The method of claim 17, wherein the step (F) further comprises:
making the jump instruction a long jump instruction when the destination of the jump instruction is not in the target group;
wherein a jump range of the short jump instruction is smaller than a jump range of the long jump instruction.
